(19) United States
(12) Patent Application Publication
(10) Pub. No.: US 2014/0175360 A1
(43) Pub. Date: Jun. 26, 2014

(54) Bilayered Oxide Structures for ReRAM Cells

(71) Applicants: Intermolecular Inc., (US); Kabushiki Kaisha Toshiba, (US); SanDisk 3D LLC, (US)

(72) Inventors: Mihir Tendulkar, Mountain View, CA (US); Vidyut Gopal, Sunnyvale, CA (US); Imran Hashim, Saratoga, CA (US); Randall J. Higuchi, San Jose, CA (US); Tim Minvielle, San Jose, CA (US); Yun Wang, San Jose, CA (US); Takeshi Yamaguchi, Kanagawa (JP)

(73) Assignees: INTERMOLECULAR INC., San Jose, CA (US); SANDISK 3D LLC, Milpitas, CA (US); KABUSHIKI KAISHA TOSHIBA, Tokyo (JP)

(21) Appl. No.: 13/721,358

(22) Filed: Dec. 20, 2012

(51) Int. Cl. H01L 45/00

(52) U.S. Cl. CPC H01L 45/146
USPC 257/4

(57) ABSTRACT

Provided are resistive random access memory (ReRAM) cells having bi-layered metal oxide structures. The layers of a bi-layered structure may have different compositions and thicknesses. Specifically, one layer may be thinner than the other layer, sometimes as much as 5 to 20 times thinner. The thinner layer may be less than 30 Angstroms thick or even less than 10 Angstroms thick. The thinner layer is generally more oxygen rich than the thicker layer. Oxygen deficiency of the thinner layer may be less than 5 atomic percent or even less than 2 atomic percent. In some embodiments, a highest oxidation state metal oxide may be used to form a thinner layer. The thinner layer typically directly interfaces with one of the electrodes, such as an electrode made from doped polysilicon. Combining these specifically configured layers into the bi-layered structure allows improving forming and operating characteristics of ReRAM cells.

### TECHNICAL FIELD

The present invention relates generally to semiconductor devices and more specifically to resistive random access memory (ReRAM) cells having bi-layered structures one layer of which exhibits resistive switching.

### BACKGROUND

Nonvolatile memory is computer memory capable of retaining the stored information even when unpowered. Non-volatile memory is typically used for the task of secondary storage or long-term persistent storage and may be used in addition to volatile memory, which losses the stored information when unpowered. Nonvolatile memory can be permanently integrated into computer systems (e.g., solid state hard drives) or can take the form of removable and easily transportable memory cards (e.g., USB flash drives). Nonvolatile memory is becoming more popular because of its small size/high density, low power consumption, fast read and write rates, retention, and other characteristics.

Flash memory is a common type of nonvolatile memory because of its high density and low fabrication costs. Flash memory is a transistor-based memory device that uses multiple gates per transistor and quantum tunneling for storing the information on its memory device. Flash memory uses a block-access architecture that can result in long access, erase, and write times. Flash memory also suffers from low endurance, high power consumption, and scaling limitations.

The constantly increasing speed of electronic devices and storage demand drive new requirements for nonvolatile memory. For example, nonvolatile memory is expected to replace hard drives in some computer systems. However, transistor-based flash memory is often inadequate to meet the requirements of various applications. New types of memory, such as resistive random access memory (ReRAM), are being developed to meet these demands and requirements.

### SUMMARY

Provided are resistive random access memory (ReRAM) cells having bi-layered metal oxide structures. The layers of a bi-layered structure may have different compositions and thicknesses. Specifically, one layer may be thinner than the other layer, sometimes as much as 5 to 20 times thinner. The thinner layer may be less than 30 Angstroms thick or even less than 10 Angstroms thick. The thinner layer is generally more oxygen rich than the thicker layer. Oxygen deficiency of the thinner layer may be less than 5 atomic percent or even less than 2 atomic percent. In some embodiments, a highest oxidation state metal oxide may be used to form a thinner layer. The thinner layer typically directly interfaces with one of the electrodes, such as an electrode made from doped polysilicon. Combining these specifically configured layers into the bi-layered structure allows improving forming and operating characteristics of ReRAM cells.

### BRIEF DESCRIPTION OF THE DRAWINGS

To facilitate understanding, the same reference numerals have been used, where possible, to designate common components presented in the figures. The drawings are not to scale and the relative dimensions of various elements in the drawings are depicted schematically and not necessarily to scale. Various embodiments can readily be understood by considering the following detailed description in conjunction with the accompanying drawings, in which:

FIGS. 1A and 1B illustrate schematic representations of a nonvolatile memory element in its high resistive state (HRS) and low resistive state (LRS), in accordance with some embodiments.

FIG. 2 illustrates a plot of a current passing through a nonvolatile memory element as a function of a voltage applied to the nonvolatile memory element, in accordance with some embodiments.

FIG. 3 illustrates a schematic representation of a ReRAM cell with a thin resistive switching layer, in accordance with some embodiments.

FIG. 4A illustrates a plot of a median set voltage as a function of a thickness and oxygen concentration of tantalum oxide resistive switching layers.

FIG. 4B illustrates a plot of a median set transient current as a function of a thickness and oxygen concentration of tantalum oxide resistive switching layers.

FIG. 4C illustrates a plot of a forming voltage as a function of a thickness and oxygen concentration of tantalum oxide resistive switching layers.

FIG. 5 illustrates a process flowchart corresponding to a method for forming a ReRAM cell, in accordance with some embodiments.

FIGS. 6A and 6B illustrate schematic views of memory arrays including multiple ReRAM cells, in accordance with some embodiments.

### DETAILED DESCRIPTION

A detailed description of various embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

### Introduction

A ReRAM cell exhibiting resistive switching characteristics generally includes multiple layers formed into a stack. This stack is often labeled as a Metal-Insulator-Metal (MIM) stack. The stack includes two conductive layers operating as electrodes, which may include metals and other conductive materials, such as doped silicon. These conductive layers are identified as “M” in the above naming convention. The stack also includes an insulator layer disposed between the electrodes. The insulator layer is indentified as “I” above. The insulator layer exhibits resistive switching properties characterized by different resistive states, which may be used to store one or more bits of information. For example, one resistive state may be used to represent a logical “zero,” while another resistive state may be used to represent a logical “one.” The insulator is often referred to as a resistive switching layer. The difference in the resistive states may be attributed to changes in the insulator layer, changes at one or both interfaces between the insulator layer and metal layers, or both types of changes.

Without being restricted to any particular theory, it is believed that the resistive switching properties of the insulator layer depend on concentration and distribution of the defects inside this layer. For example, oxygen vacancies in metal oxides are believed to be responsible for different resistive states depending on their distribution within the resistive switching layer and may be used to form conductive paths with metal oxide structures resulting in lower resistive states. Reorientation of the oxygen vacancies may break previously established conductive paths resulting in higher resistive states.

In order for metal oxides to start exhibiting their switching characteristics, the oxides often need to be electroformed. Sometimes this electroforming operation is simply referred to as forming. This operation typically needs to be performed only once after depositing a metal oxide into a ReRAM cell and prior to operating the cell. It is believed that this forming operation generates and/or organizes oxygen vacancies within the metal oxide structure in a manner that allows subsequent resistive switching. The forming typically requires higher voltages (e.g., 3-7V) than, for example, switching operations (e.g., less than 3V). Subjecting a ReRAM cell to such high voltages even once may cause unforeseen impacts on its switching behavior. Many developers currently struggle to design ReRAM cells with repeatable performance. It is understood that high forming voltages need to be avoided.

More control over the resistive switching behavior of metal oxides may be achieved by reducing the thicknesses of structures formed from these oxides. It has been demonstrated that conductive paths in metal oxide structures rupture and reconnect within 5-10 Angstrom regions of these structures at interfaces with electrodes. This behavior has been observed for titanium oxide, tantalum oxide, and hafnium oxide. The remaining parts of the metal oxide structures operate as static conductors and generally do not participate in switching. As such, some form of conductivity needs to be established through these remaining parts.

In many conventional ReRAM cells, the same metal oxide layer is used to form both the switching portion and static conducting portions of this layer during this forming operation. Specifically, large forming voltages are used to form oxygen vacancies in an entire layer and to establish initial conductivity in the ReRAM cell. While the two portions are clearly distinguishable after the electroforming, they usually start as the same layer. As such, the two portions have substantially the same level of oxygen deficiencies.

Forming voltages may be reduced by minimizing any part of the structure that requires alignment of the oxygen vacancies. In some embodiments, the forming voltages may be reduced by reducing the thickness of the switching portion and/or the static portion. In some embodiments, the forming voltages may be reduced by selecting a material for the static portion that does not require forming to exhibit conductivity. In an extreme example, the metal oxide structure includes only the switching region and the static conduction portion is absent from the ReRAM cell. Depositing a thin metal oxide layer may help with lowering forming voltages. Scaling down the thickness also helps with reducing voltages that are used to change the resistance of the structure from its high state to its low state, which is often referred to as a SET voltage. However, such scaling has the opposite effect on voltages that are used to change the resistance of the structure from its low state to its high state, which is often referred to as a RESET voltage. As structures get too thin, they are more prone to tunneling effects. Furthermore, materials become more sensitive to defect generation and ReRAM cells may experience excessive currents during switching and reading due their low resistance cause by absence of the static layer.

Provided are ReRAM cells having bi-layered metal oxide structures. The two types of layers in such structures may have different compositions and thicknesses. Specifically, one layer may be thinner than the other layer, sometimes as much as about 5 to 20 times thinner. The thinner layer may be less than about 30 Angstroms thick or even less than about 10 Angstroms thick, e.g., between about 5 Angstroms and 10 Angstroms. As such, this thickness is comparable to the thickness of the switching region described above. The thicker layer may be between about 50 Angstroms and 1000 Angstrom thick in order to provide adequate resistance with the ReRAM cell. This thickness generally depends on resistivities of materials used for thicker layers. These resistivities may be changed during initial electroforming but may stay substantially constant during later operations.

The thicker layer is generally more oxygen deficient than the thinner layer, which makes it easier to form conductive paths through both layers and help to reduce forming voltages. The oxygen deficiency (as defined herein) of the thinner layer may be less than about 5 atomic percent or even less than about 2 atomic percent. In some embodiments, the oxygen deficiency of the thicker layer may be at least about 5 atomic percent. However, excessive concentrations of oxygen deficiencies in the thicker layer may result in an unsuitably small resistivity of this layer and should be generally avoided. In some embodiments, the concentration of oxygen deficiencies in the thicker layer is less than about 20 atomic percent. In some embodiments, a highest oxidation state metal oxide may be used to form a thinner layer.

Some examples of suitable materials for the two layers of the bi-layered structure include titanium oxide, tantalum oxide, niobium oxide, and aluminum oxide. In some embodiments, both layers are formed from the same kind of oxides (e.g., tantalum oxide) but the thicker layer has a higher concentration of oxygen deficiencies than the bottom layer. For example, the composition of the thinner layer may be expressed with one of the following formulas: TiO₂, Nb₂O₅, Ta₂O₅, and Al₂O₃. These are examples of highest oxidation state metal oxides, which are not oxygen deficient. The composition of the thicker layer may be expressed with one of the following formulas: T₄O₇, NbO₂, TaO₂, and AlO₂. These are examples of stoichiometric oxides, but these are not highest oxidation state metal oxides. As such, this second group of oxides has some oxygen deficiency.

For purposes of this disclosure, stoichiometric metal oxides that are not highest oxidation state metal oxides are referred to as “sub-oxides”. As such, T₄O₇, NbO₂, TaO₂, and AlO₂ are examples of sub-oxides. Many sub-oxides are relatively stable materials in comparison to their non-stoichiometric counterparts. This stability may translate into stable performance of the ReRAM cells, such as consistent resistance characteristics during operation of the cells. In some embodiments, non-stoichiometric oxides may be used for the thinner layer and/or for thicker.

For purposes of this disclosure, “oxygen deficiency” is defined as any excess of metal and/or absence of oxygen in an oxide relative to the ideal highest oxidation state metal oxide. For each metal, there is typically only one highest oxidation state metal oxide, e.g., TiO₂, NB₂O₅, Ta₂O₅, and Al₂O₃. The highest oxidation state metal oxide will not oxidize further even if exposed to very favorable oxidation conditions, e.g., annealing at 400° C. for 30 min in 100% oxygen environment. As such, any metal oxide that has a higher atomic concentration ratio of its metal to oxygen than the ideal highest oxidation state metal oxide is considered to be oxygen deficient and, therefore, has a concentration of oxygen deficiencies that is greater than 0 atomic percent. For example, titanium dioxide (TiO₂) has no oxygen deficiency in its ideal form, i.e., or its concentration of oxygen deficiencies is 0 atomic percent. At the same time, a stoichiometric variation of titanium oxide Ti₄O₇ has about 3 atomic percent of oxygen deficiencies based on oxygen concentration of 66.67 atomic percent in TiO₂ and 63.64 atomic percent in Ti₄O₇. Oxygen deficient metal oxides may be in a stable stoichiometric form, e.g., Ti₄O₇, NbO₂, TaO₂, AlO₂, or they may be in a non-stoichiometric form, e.g., TiO_{1.8}.

Oxygen vacancies may be present and/or formed in oxygen deficient metal oxides and even in highest oxidation state metal oxides that are not oxygen deficient. While the description generally refers to oxygen vacancies as building blocks of conductive paths, other conductive mechanisms are also within the scope of this disclosure.

Examples of Re-RAM Cells and their Switching Mechanisms

A brief description of ReRAM cells and their switching mechanisms are provided for better understanding of various features and structures associated with ReRAM cells and, more specifically, with bi-layered structures further described below. ReRAM is a non-volatile memory type that includes dielectric material exhibiting resistive switching characteristics. A dielectric, which is normally insulating, can be made to conduct through one or more filaments or conduction paths formed after application of a sufficiently high voltage. The conduction path formation can arise from different mechanisms, including defects, metal migration, and other mechanisms further described below. Once the one or more filaments or conduction paths are formed in the dielectric component of a memory device, these filaments or conduction paths may be reset (or broken resulting in a high resistance) or set (or re-formed resulting in a lower resistance) by applying certain voltages.

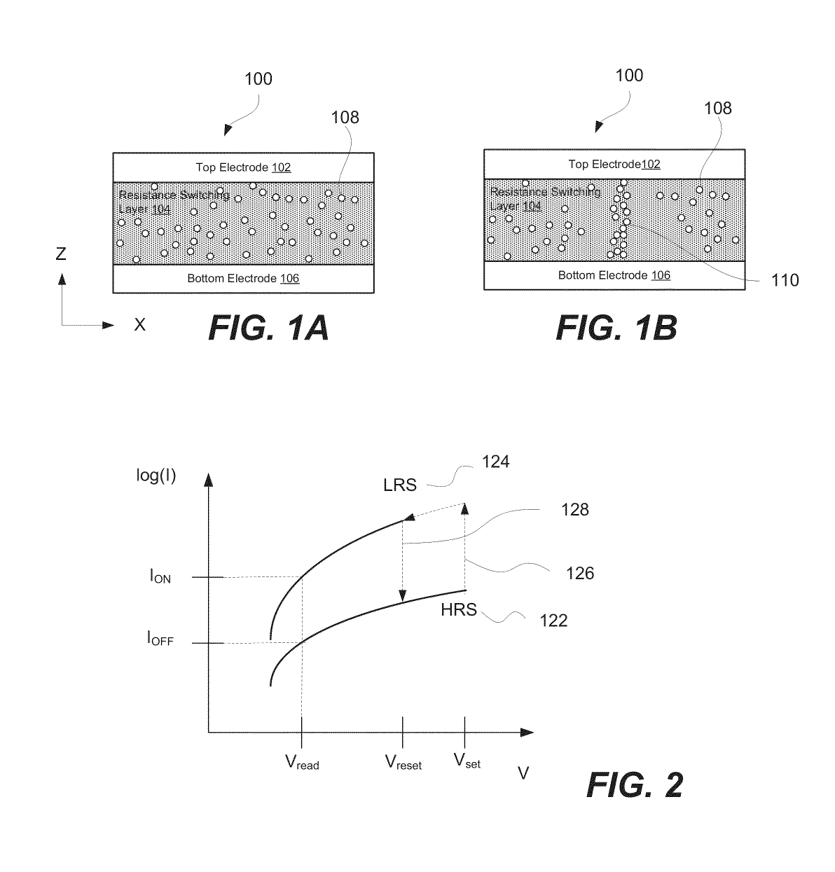

A basic building unit of a memory device is a stack having a capacitor like structure. A ReRAM cell includes two electrodes and a dielectric positioned in between these two electrodes. FIG. 1A illustrates a schematic representation of ReRAM cell 100 including top electrode 102, bottom electrode 106, and resistance switching layer 104 provided in between top electrode 102 and bottom electrode 106. It should be noted that the “top” and “bottom” references for electrodes 102 and 106 are used solely for differentiation and not to imply any particular spatial orientation of these electrodes. Often other references, such as “first formed” and “second formed” electrodes or simply “first” and “second”, are used identify the two electrodes. ReRAM cell 100 may also include other components, such as an embedded resistor, diode, and other components. ReRAM cell 100 is sometimes referred to as a memory element or a memory unit.

As stated above, resistance switching layer 104, which is made of a dielectric material, can be made to conduct through one or more filaments or conduction paths formed by applying a certain voltage. To provide this resistive switching functionality, resistance switching layer 104 includes a certain concentration of electrically active defects 108, which are sometimes referred to as traps. For example, some charge carriers may be absent from the structure (i.e., vacancies) and/or additional charge carriers may be present (i.e., interstitials) representing defects 108. In some embodiments, defects may be formed by impurities (i.e., substitutions). These defects may be utilized for ReRAM cells operating according to a valence change mechanism, which may occur in specific transition metal oxides and is triggered by a migration of anions, such as oxygen anions. Migrations of oxygen anions may be represented by the motion of the corresponding vacancies, i.e., oxygen vacancies. A subsequent change of the stoichiometry in the transition metal oxides leads to a redox reaction expressed by a valence change of the cation sublattice and a change in the electronic conductivity. In this example, the polarity of the pulse used to perform this change determines the direction of the change, i.e., reduction or oxidation. Other resistive switching mechanisms include bipolar electrochemical metallization mechanism and thermochemical mechanism, which leads to a change of the stoichiometry due to a current-induced increase of the temperature.

Without being restricted to any particular theory, it is believed that defects 108 can be reoriented within resistance switching layer 104 to form filaments or conduction paths as, for example, schematically shown in FIG. 1B as element 110. This reorientation of defects 108 occurs when a voltage for this type of resistance switching layer 104 is applied to electrodes 102 and 106. Sometimes, reorientation of defects 108 is referred to as filling the traps by applying a set voltages (and forming one or more filaments or conduction paths) and emptying the traps by applying a reset voltage (and breaking the previously formed filaments or conduction paths).

Defects 108 can be introduced into resistance switching layer 104 during or after its fabrication. For example, a certain concentration of oxygen deficiencies can be introduced into metal oxides during their deposition or during subsequent annealing. Physical vapor deposition (PVD) and atomic layer deposition (ALD) techniques may be specifically tuned to include particular defects 108 and their distribution within resistance switching layer 104.

Operation of ReRAM cell 100 will now be briefly described with reference to FIG. 2 illustrating a logarithmic plot of a current passing through a ReRAM cell as a function of a voltage applied to the electrode of ReRAM cell, in accordance with some embodiments. ReRAM cell 100 may be configured to have either unipolar switching or bipolar switching. For simplicity, FIG. 2 illustrates a unipolar configuration. Those skilled in the art will understand that the disclosure herein may also be applied to a bipolar configuration. ReRAM cell 100 may be either in a low resistive state (LRS) defined by line 124 or high resistive state (HRS) defined by line 122. Each of these states is used to represent a different logic state, e.g., HRS representing logic one and LRS representing logic zero or vice versa. Therefore, each ReRAM cell that has two resistance states may be used to store one bit of data. It should be noted that some ReRAM cells may have three and even more resistance states allowing multi-bit storage in the same cell.

HRS and LRS are defined by presence or absence of one or more filaments or conduction paths in resistance switching layer 104 and forming connections between these filaments or conduction paths and two electrodes 102 and 106. For example, a ReRAM cell may be initially fabricated in LRS and then switched to HRS. A ReRAM cell may be switched back and forth between LRS and HRS many times, defined by set and reset cycles. Furthermore, a ReRAM cell may maintain its LRS or HRS for a substantial period of time and withstand a number of read cycles.

The overall operation of ReRAM cell 100 may be divided into a read operation, set operation (i.e., turning the cell “ON”), and reset operation (i.e., turning the cell “OFF”). During the read operation, the state of ReRAM cell 100 or, more specifically, the resistance of resistance switching layer 104 can be sensed by applying a sensing voltage to electrodes 102 and 106. The sensing voltage is sometimes referred to as a “READ” voltage and indicated as V_{READ} in FIG. 2. If ReRAM cell 100 is in HRS represented by line 122, the external read and write circuitry connected to electrodes 102 and 106 will sense the resulting “OFF” current (I_{OFF}) that flows through ReRAM cell 100. As stated above, this read operation may be performed multiple times without switching ReRAM cell 100 between HRS and LRS. In the above example, the ReRAM cell 100 should continue to output the “OFF” current (I_{OFF}) when the read voltage (V_{READ}) is applied to the electrodes.

Continuing with the above example, when it is desired to switch ReRAM cell 100 into a different logic state, ReRAM cell 100 is switched from its HRS to LRS. This operation is referred to as a set operation. This may be accomplished by using the same read and write circuitry to apply a set voltage (V_{SET}) to electrodes 102 and 106. Applying the set voltage (V_{SET}) forms one or more filaments or conduction paths in resistance switching layer 104 and switches ReRAM cell 100 from its HRS to LRS as indicated by dashed line 126. It should be noted that formation or breaking of filaments or conduction paths in resistance switching layer 104 may also involve forming or breaking electronic connections between these filaments and one (e.g., reactive electrode) or both electrodes. The overarching concern is passage of the current between the two electrodes.

In LRS, the resistance characteristics of ReRAM cell 100 are represented by line 124. In this LRS, when the read voltage (V_{READ}) is applied to electrodes 102 and 106, the external read and write circuitry will sense the resulting “ON” current (I_{ON}) that flows through ReRAM cell 100. Again, this read operation may be performed multiple times without switching ReRAM cell 100 between LRS and HRS.

It may be desirable to switch ReRAM cell 100 into a different logic state again by switching ReRAM cell 100 from its LRS to HRS. This operation is referred to as a reset operation and should be distinguished from set operation during which ReRAM cell 100 is switched from its HRS to LRS. During the reset operation, a reset voltage (V_{RESET}) is applied to ReRAM cell 100 to break the previously formed filaments or conduction paths in resistance switching layer 104 and switches ReRAM cell 100 from its LRS to HRS as indicated by dashed line 128. Reading of ReRAM cell 100 in its HRS is described above. Overall, ReRAM cell 100 may be switched back and forth between its LRS and HRS many times. Read operations may be performed in each of these states (between the switches) one or more times or not performed at all. It should be noted that application of set and reset voltages to change resistance states of the ReRAM cell involves complex mechanisms that are believed to involve localized resistive heating as well as mobility of defects impacted by both temperature and applied potential.

ReRAM cell 100 may be configured to have either unipolar switching or bipolar switching. The unipolar switching does not depend on the polarity of the set voltage (V_{SET}) and reset voltage (V_{RESET}) applied to the electrodes 102 and 106 and, as a result, to resistance switching layer 104. In the bipolar switching the set voltage (V_{SET}) and reset voltage (V_{RESET}) applied to resistance switching layer 104 need to have different polarities.

In some embodiments, the set voltage (V_{SET}) is between about 100 mV and 10V or, more specifically, between about 500 mV and 5V. The length of set voltage pulses (t_{SET}) may be less than about 100 milliseconds or, more specifically, less than about 5 milliseconds and even less than about 100 nanoseconds. The read voltage (V_{READ}) may be between about 0.1 and 0.5 of the write voltage (V_{SET}). In some embodiments, the current during reading and writing operations may be less than about 5 μA or, more specifically, is less than about 1 μA. The length of read voltage pulse (t_{READ}) may be comparable to the length of the corresponding set voltage pulse (t_{SET}) or may be shorter than the write voltage pulse (t_{SET}).

A ratio of currents generated during set and reset operations may be at least about 5 or, more specifically, at least about 10 to make the state of ReRAM cell easier to determine. ReRAM cells should be able to cycle between LRS and HRS between at least about 10̂3 times or, more specifically, at least about 10̂7 times without failure. A data retention time (t_{RET}) should be at least about 5 years or, more specifically, at least about 10 years at a thermal stress up to 85° C. and small electrical stress, such as a constant application of the read voltage (V_{READ}).

In some embodiments, the same ReRAM cell may include two or more resistance switching layers interconnected in series. Adjacent resistance switching layers may directly interface each other or be separated by an intermediate layer.

In some embodiments, a ReRAM cell is subjected to a forming operation, during which the initially insulating properties of the resistance switching layer are altered and the ReRAM cell is configured into the initial LRS or HRS. The forming operation may include a very short high discharge current peak, which is used to set the LRS level of the resistance switching layer for subsequent switching as outlined above. In this case, a resistance switching layer with very low levels (e.g., 100-30 kOhm) of resistance in the LRS may be limited in terms of scaling down. This difficulty may be resolved by positioning such resistance switching layers in series with other components providing additional resistance to the overall ReRAM cell.

ReRAM Cell Components and their Characteristics

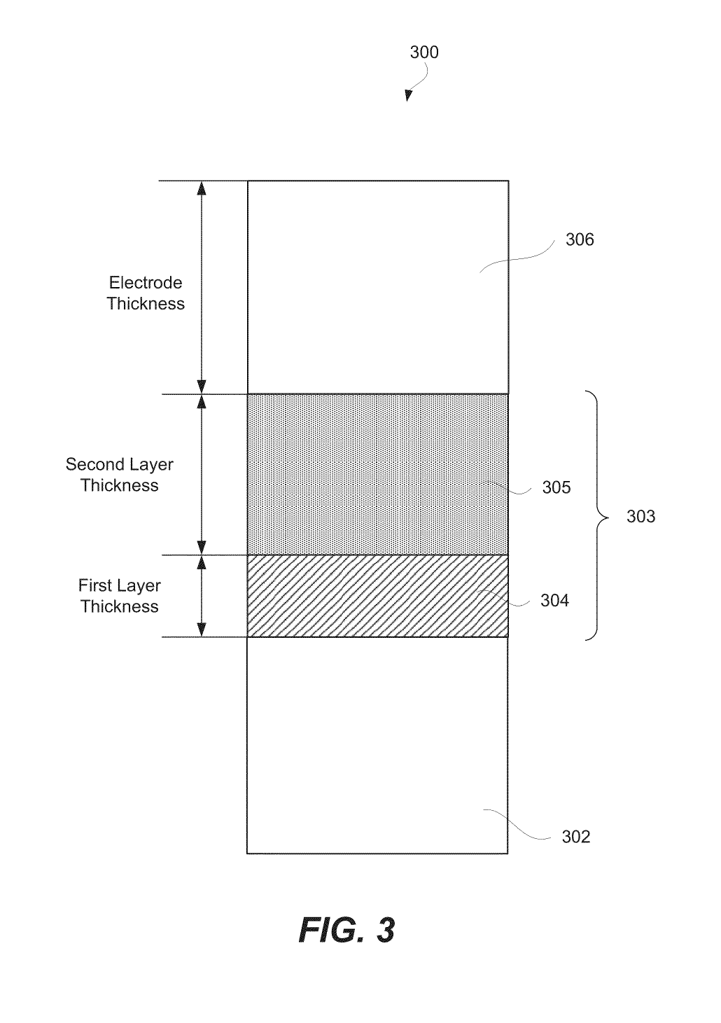

FIG. 3 illustrates a schematic representation of ReRAM cell 300, in accordance with some embodiments. ReRAM cell 300 includes a first electrode 302, a second electrode 306, and a bi-layered structure 303 disposed between two electrodes 302 and 306. Bi-layered structure 303 includes a first layer 304 and a second layer 306. The “first” and “second” terminology is used herein only for differentiating reasons and does not imply any deposition order or spatial orientation of the layers unless specifically noted. First layer 304 may be thinner than second layer 305. Furthermore, first layer 304 may be formed from a metal oxide that has fewer oxygen deficiencies than a metal oxide of second layer. This oxygen deficiency variation may be created during deposition or subsequent processing (e.g., hydrogen annealing) of the layers and prior to electroforming. In some embodiments, ReRAM cell 300 may include other elements, such as a diode, a coupling layer, a diffusion barrier layer, and/or one or more additional resistive switching layers.

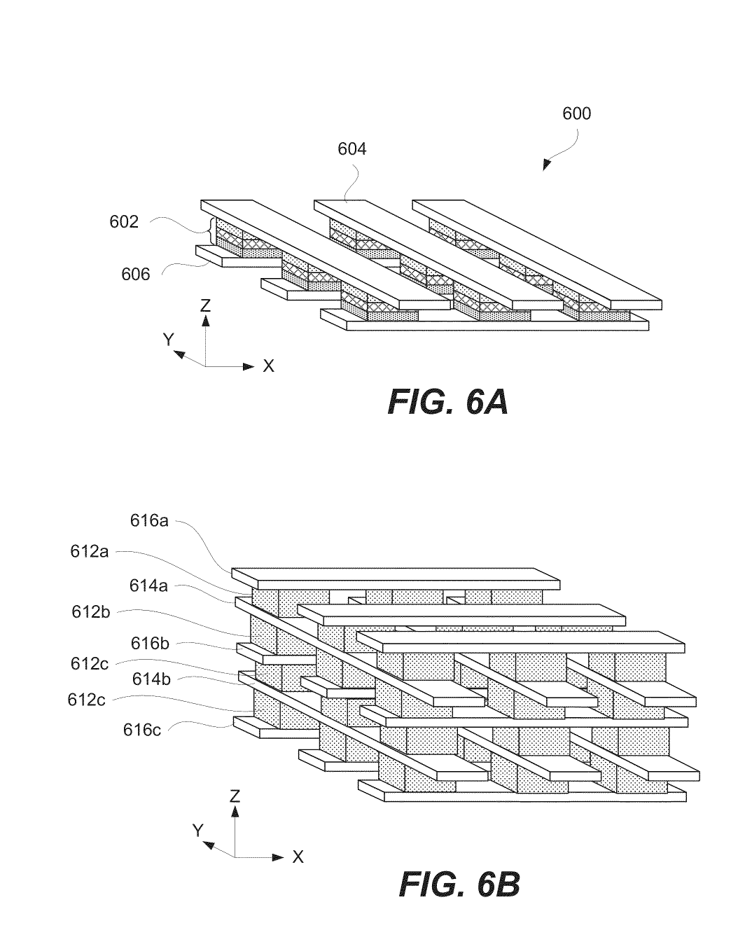

First electrode 302 and second electrode 306 provide electrical connections to ReRAM cell 300. In some embodiments, first electrode 302 and/or second electrode 306 are parts of signal lines that extend between multiple ReRAM cells, which may be cells provided in the same row or column a memory array as further described below with reference to FIGS. 6A and 6B. In some embodiments, first electrode 302 and/or second electrode 306 may be separate components from the signal lines. For example, first electrode 302 or second electrode 306 may be an intermediate electrode and additional components, such as a diode may be provided between this electrode and a signal line.

First electrode 302 and second electrode 306 are typically made from conductive materials. Some examples of suitable electrode materials include n-doped polysilicon, titanium nitride, ruthenium, iridium, platinum, tantalum nitride, tantalum silicon nitride, titanium silicon nitride, tantalum aluminum nitride, tantalum boron nitride, titanium aluminum nitride, and titanium boron nitride. These electrode materials may be conceptually divided into active electrode materials and passive electrode materials thereby resulting in active electrode and passive electrodes. The distinction is based on the relative reactivity (e.g. with respect to oxygen) of materials at interfaces formed by these electrodes. An active electrode generally directly interfaces a resistive switching layer and has a larger amount of reactivity at this interface than the passive electrode. The passive electrode may also directly interface with the resistive switching layer or it may be separated from the resistive switching layer by other layers, such as current limiting layers and even diffusion barrier layers. For example, doped polysilicon is considered to be an active electrode material, while titanium nitride is considered to be a passive electrode material, at least with reference to metal oxides used for resistive switching layers. Other examples of active electrode materials include titanium, nickel, tantalum, hathium, and aluminum. Other examples of passive electrode materials include titanium silicon nitride, tantalum nitride, tantalum silicon nitride, noble metals such as gold, silver, platinum, and conductive oxides such as irdium oxide, molybdenum oxide, and indium tin oxide.

In some embodiments, first electrode 302 is an active electrode and it directly interfaces first layer 304. Second electrode 306 may be a passive electrode. First electrode 302 may be made from doped polysilicon or, more specifically, from n-doped polysilicon. Second electrode 306 may be made from titanium nitride, titanium silicon nitride, tantalum nitride, tantalum silicon nitride, noble metals such as gold, silver, platinum, and conductive oxides such as irdium oxide, molybdenum oxide, and indium tin oxide.

In some embodiments, second electrode 306 does not directly interface second layer 305. In some embodiments, a diffusion barrier layer (not shown) is disposed between second electrode 306 and second layer 305. A diffusion barrier may be made from suitable oxygen blocking materials, such as titanium nitride, tantalum nitride, tantalum silicon nitride, titanium silicon nitride, tantalum aluminum nitride, tantalum boron nitride, titanium aluminum nitride, and titanium boron nitride. In some embodiments, the diffusion barrier layer is less than about 100 Angstroms thick, for example, between 25 Angstroms and 75 Angstroms thick, such as about 50 Angstroms thick. In some embodiments, a diffusion barrier layer may be provided within bi-layered structure 303, i.e., between first layer 304 and second layer 305. First electrode 302 and/or second electrode 306 may have a thickness of less than about 1,000 Angstroms, such as less than about 500 Angstroms and even less than about 100 Angstroms. Thinner electrodes may be formed using ALD techniques.

Some examples of metal oxides suitable for first layer 304 and second layer 305 include titanium oxide, tantalum oxide, niobium oxide, or aluminum oxide. In some embodiments, metals forming oxides used for both first layer 304 and second layer 305 are capable of forming two stable stoichiometric oxides, i.e., one highest oxidation state metal oxide provided in first layer 304 and one stoichiometric sub-oxide provided in second layer 305. As described above, the highest oxidation state metal oxide is substantially free from oxygen deficiencies, while the stoichiometric sub-oxide has some oxygen deficiencies. It should be noted that some metals, e.g., hafnium and nickel, do not have multiple stable forms of their oxides.

In some embodiments, first layer 304 may be formed from TiO₂, while second layer 305 may be formed from Ti₄O₇. In some embodiments, first layer 304 may be formed from Nb₂O₅, while second layer 305 may be formed from NbO₂. In some embodiments, first layer 304 may be formed from Ta₂O₅, while second layer 305 may be formed from TaO₂. Finally, the first layer 304 may be formed from Al₂O₃, while second layer 305 may be formed from AlO₂.

In some embodiments, non-stoichiometric oxides may be used for one or both layers. For example, first layer 304 may be formed from the highest oxidation state metal oxide, while second layer 305 may be formed from a corresponding non-stoichiometric stoichiometric oxide.

Oxides of both layers may include the same metal, e.g., titanium, niobium, tantalum, and aluminum, or different metals, e.g., a combination of tantalum oxide and aluminum oxide may be used in the same bi-layered structure. In this example, aluminum oxide may be used for second layer 305 since this oxide is relatively easy to integrate.

Metal oxides used for first layer 304 and second layer 305 can be differentiated based on their oxygen deficiency. In general, second layer 305 is more oxygen deficient than first layer 304. In some embodiments, this oxygen deficiency difference is at least about 3 atomic percent or, more specifically, at least about 5 atomic percent and even at least about 10 atomic percent. First layer 304 may include some oxygen deficiency or it may be the highest oxidation state metal oxide having substantially no oxygen deficiencies. In some embodiments, first layer 304 has oxygen deficiency of less than 5 atomic percent or, more specifically, less than 2 atomic percent. Oxygen deficiency of second layer 305 may be at least about 5 atomic percent or, more specifically, at least about 10 atomic percent. In some embodiments, oxygen deficiency of second layer 305 may be less than about 20 atomic percent or even less than 15 atomic percent. Excessive oxygen deficiency may result in a resistivity being too low.

Selection of materials for first layer 304 and second layer 305 determine at least in part some characteristics of these layers. In some embodiments, first layer 304 has a breakdown field of between 1 MV/CM and 5 MV/cm. In some embodiments, second layer 305 has a breakdown field of greater than 5 MV/cm. In some embodiments, first layer 304 has a resistivity of greater than 10̂ 11 Ohm-cm. In some embodiments, second layer 305 has a resistivity of between 10̂4 Ohm-cm and 10̂7 Ohm-cm.

First layer 304 is generally much thinner than second layer 305. In some embodiments, the thickness of first layer 304 is between about five and twenty times smaller than the thickness of second layer 305 or, more specifically, about five and ten times smaller. In some embodiments, first layer 304 has a thickness of less than 20 Angstroms or, more specifically, less than 10 Angstroms, e.g., between about 5 Angstroms and 10 Angstroms. The thickness of second layer 305 may be at least 20 Angstroms or, more specifically at least about 50 Angstroms, or even at least about 100 Angstroms. In some embodiments, the thickness of second layer 305 is at less than 1000 Angstroms or, more specifically. Less than about 500 Angstroms.

In some embodiments, ReRAM cell 300 includes first and second electrodes 302 and 306 for making a first electrical connection to the resistive random access memory cell. First electrode 302 may be made from n-doped polysilicon, while second electrode 306 may be made from titanium nitride. This ReRAM cell 300 also includes a bi-layered structure 303 provided in between first and second electrodes 302 and 306. Bi-layered structure include first layer 304 made from tantalum oxide defined by a stoichiometric formula of Ta₂O₅ and second layer 306 comprising tantalum oxide defined by a stoichiometric formula of TaO₂. First layer 304 exhibits resistive switching between two resistive states, i.e., LRS and HRS, which is used to store data. First layer 304 has a thickness of between about 5 Angstroms and 10 Angstroms and directly interfaces first electrode 302. Second layer 305 has a thickness of between about 30 Angstroms and 100 Angstroms and is capable of withstanding a breakdown field of least 5 MV/cm. In some embodiments, this ReRAM cell 300 also includes a diffusion barrier layer made from TiSiN and disposed between second layer 305 and second electrode 306.

### Thickness Considerations of Resistive Switching Layer

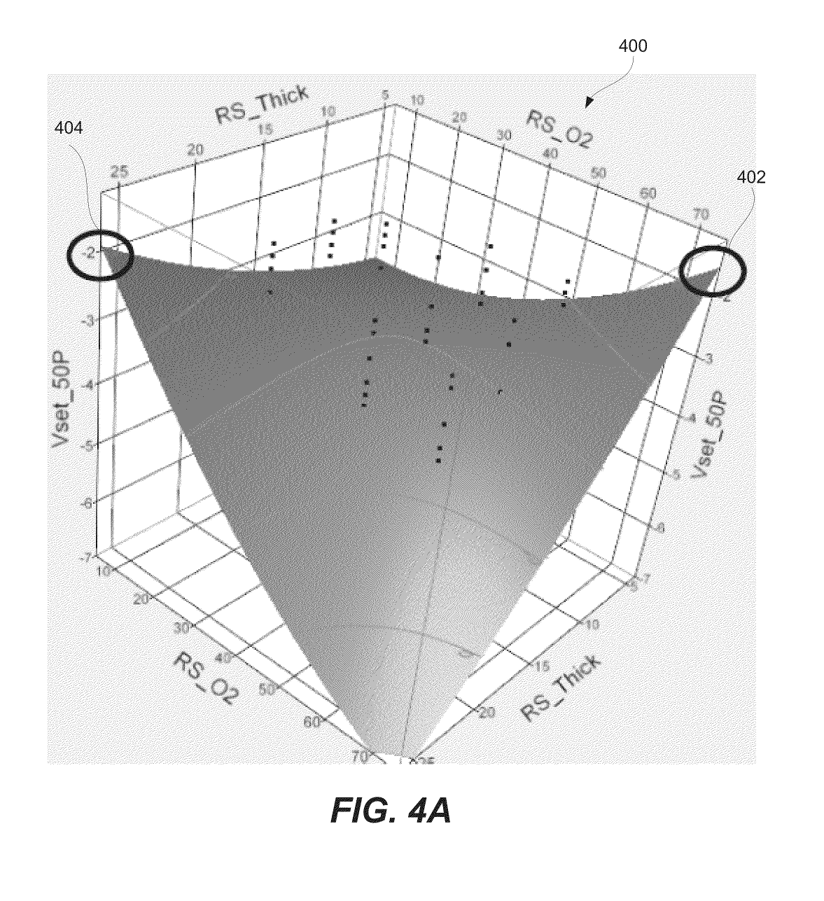

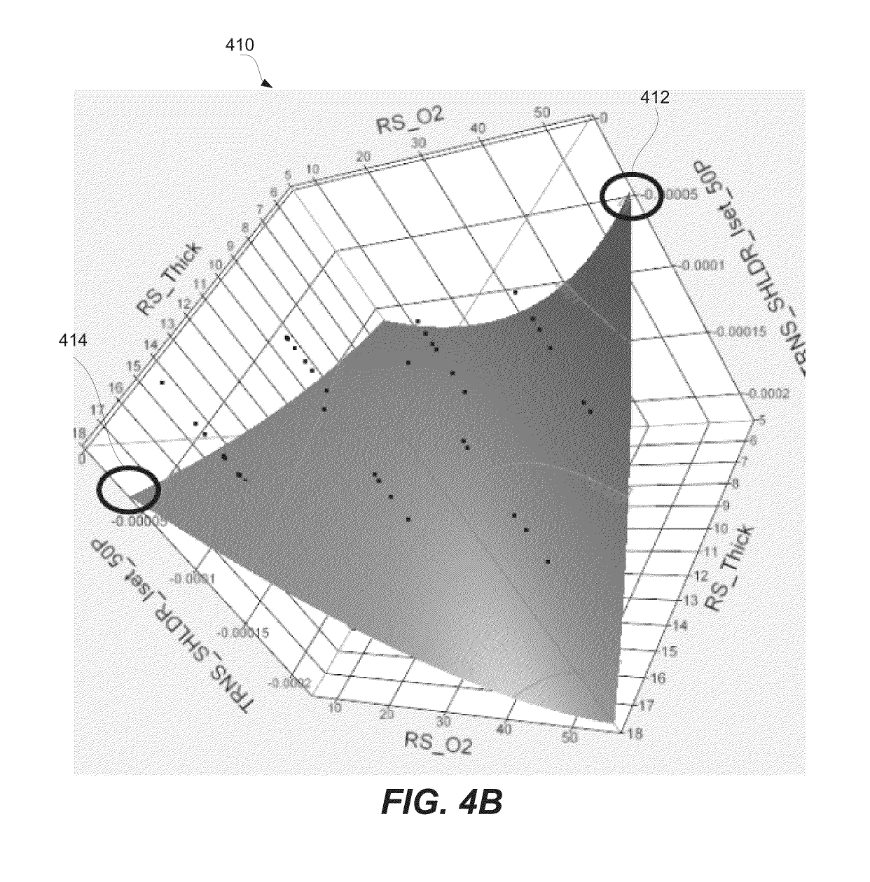

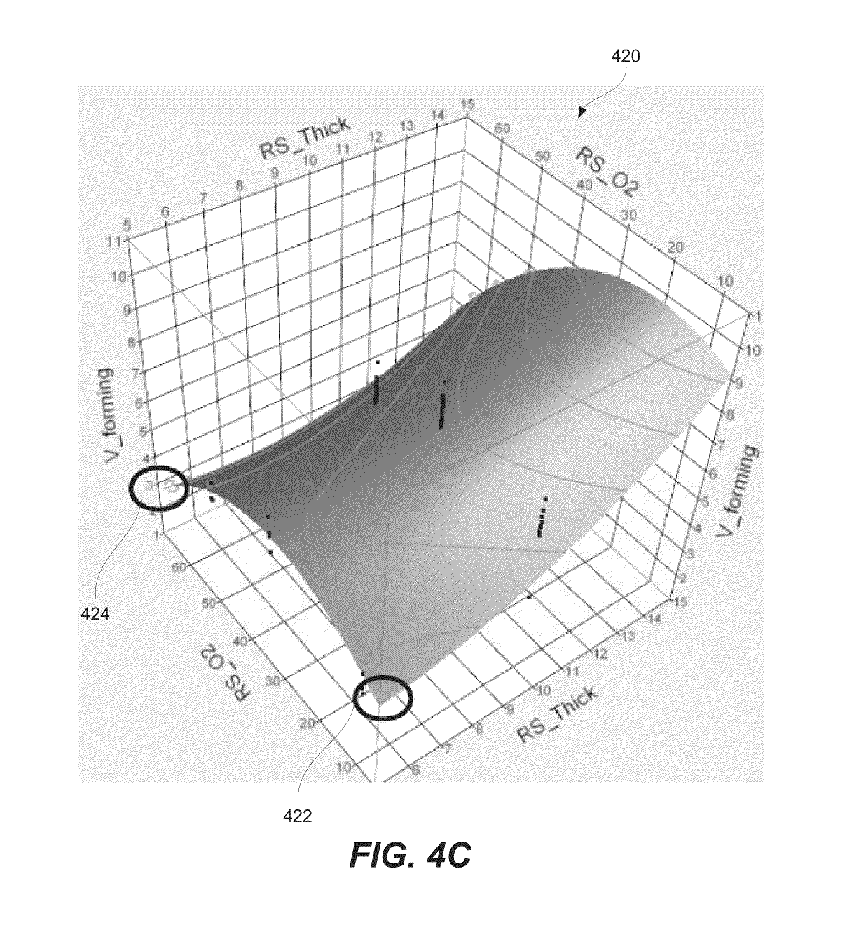

Various performance considerations for specifying thicknesses of resistive switching layers will now be described with reference to FIGS. 4A-4C. Specifically, FIG. 4A illustrates a plot 400 of a median set voltage (the vertical axis—Vset_50P) as a function of the thickness (the right horizontal axis—RS_Thick) and oxygen concentration (the left horizontal axis—RS_O2) in resistive switching layers containing tantalum oxide. The data were collected for about 300 cycles per bit for each condition. The response surface was generated using commercial statistical software (i.e. JMP™ Software from SAS). As stated above, the set voltage generally needs as small as possible, for example, less than 2 Volts. As such, the optimal characteristics of resistive switching layers are represented by points located in the top portions of the plot, i.e., closer to the zero plane. Two sets of such optimal characteristics are identified with circles 402 and 404 in FIG. 3B. The left circle 404 corresponds to a resistive switching containing a low oxygen concentration oxide (i.e., metal rich oxide) that is 25 nanometers thick. The right circle 402 corresponds to another resistive switching layer that is formed from a high oxygen concentration oxide (i.e., oxygen rich oxide) that is 5 nanometers thick. While both layers demonstrate substantially the same performance in terms of the set voltage, the thinner layer will be easier to integrate into ICs and 3D memory architectures as explained above.

FIG. 4B illustrates a plot 410 of median values for a set transient (the vertical axis—TRSN_SHLDR_Iset_50P) as a function of the thickness (the right horizontal axis—RS_Thick) and oxygen concentration (the left horizontal axis—RS_O2) in resistive switching layers containing tantalum oxide. As stated above, the set transient is a current overshoot through by the switching layer during a set operation. The set transient may need to be less than 50 micro Amperes in some embodiments (corresponding to 0.00005 on the vertical axis). As with FIG. 3B, the optimal characteristics of resistive switching layers are represented by points located in the top portions of the plot, i.e., closer to the zero plane. Two sets of such optimal characteristics are identified with circles 412 and 414 in FIG. 3C. The left circle 414 corresponds to a resistive switching containing a low oxygen concentration oxide (i.e., metal rich oxide) that is 18 nanometers thick. The right circle 412 corresponds to another resistive switching layer that is formed from a high oxygen concentration oxide (i.e., oxygen rich oxide) that is 5 nanometers thick. Again, while both layers demonstrate substantially the same performance in terms of the set voltage, the thinner layer will be easier to integrate into ICs and 3D memory architectures as explained above.

FIG. 4C illustrates a plot 420 of a forming voltage (the vertical axis—V_forming) as a function of the thickness (the right horizontal axis—RS_Thick) and oxygen concentration (the left horizontal axis—RS_O2) in resistive switching layers containing tantalum oxide. A forming voltage is applied initially to a newly fabricated ReRAM cell to shift it into its first low resistive state. Generally, forming voltages are higher than set voltages, but it is desirable to keep both types of voltages as low as possible to minimize power consumption and degradation of the ReRAM cell. As such, the optimal characteristics of resistive switching layers are represented by points located in the bottom portions of the plot, i.e., closer to the zero plane. Two sets of such optimal characteristics are identified with circles 422 and 424. Here, the strongest determinant is the thickness, since both circles 422 and 424 correspond to the layers that are 5 nanometers thick. Oxygen concentration does not have substantial impact on the forming voltages.

### Processing Examples

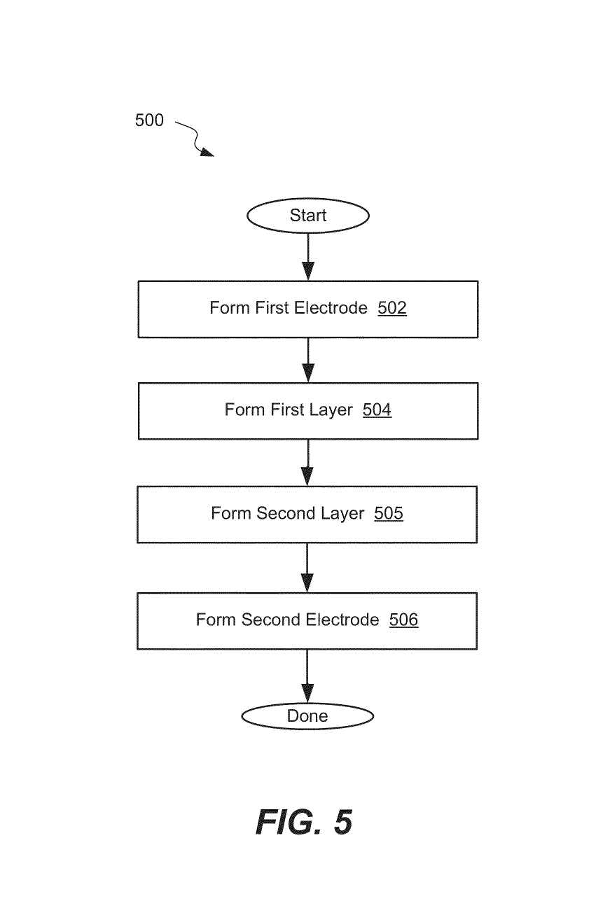

FIG. 5 illustrates a process flowchart corresponding to a method 500 for forming a ReRAM cell, in accordance with some embodiments. Various examples of the formed ReRAM cells are described above. Although illustrative processing techniques and process parameters are described, it is understood that various other techniques and modifications of the techniques may also be used. Method 500 may commence with operation 502, during which the first electrode is formed. In some embodiments, the first electrode includes doped polysilicon. The doped polysilicon may be formed using CVD or any other suitable deposition technique.

Method 500 may proceed with forming the first layer of the bi-layers structure during operation 504. This operation is followed by forming the second layer of the same bi-layers structure during operation 505. In some embodiments, both operations are performed in an uninterrupted manner such deposition of the first layer is immediately followed by deposition of the second layer, or vice versa. For example, both layers may be deposited using reactive sputtering by bombarding a metal target in an oxygen containing environment. Switching from operation 504 to operation 505 may involve reduction of the oxygen concentration in the processing chamber. The metal target may be continuously bombarded during this switching.

The first layer and/or the second layer may be deposited using PVD or other suitable techniques. For example, a tantalum oxide layer may be formed using reactive sputtering by employing a metal tantalum target in a 20-60 atomic % oxygen atmosphere. For example, if tantalum oxide is also used as the second layer, the oxygen concentration in the sputtering atmosphere is generally lower and the layer may be formed using reactive sputtering by employing a metal tantalum target in a 1-4 atomic % oxygen atmosphere. Power of 100-1000 Watts (W) may be used to achieve deposition rates of between about 0.1 and 1.0 Angstroms per second. These process parameters are provided as examples and generally depend on deposited materials, tools, deposition rates, and other factors. Other processing techniques, such as ALD, PLD, CVD, evaporation, and the like can also be used to deposit the resistive switching layer. For example, ALD can be used to form a tantalum oxide layer using hafnium precursors, such as pentakis (dimethylamino) tantalum, tris(diethylamido) (tert-butylimido) tantalum, tris(diethylamido) (ethylimido) tantalum, tris(ethylmethylamido) (tert-butylimido) tantalum, and a suitable oxidant, such as water, oxygen plasma, or ozone.

Method 500 may proceed with operation 506, during which the second electrode is formed. The second electrode may be formed from titanium nitride. The titanium nitride electrode may be formed using PVD or another process described above. Specifically, a titanium target may be sputtered at 150-500W with a pressure of 2-10 mTorr in a nitrogen environment. The duration of the sputtering can determine the thickness of the electrode. Other processing techniques, such as ALD, PLD, CVD, evaporation, and the like can also be used to deposit the second electrode.

In some embodiments, method 500 includes deposition of a diffusion barrier layer. As stated above, the diffusion barrier layer may be provided between the first layer and the second layer and/or between the second layer and the electrode. Examples of suitable diffusion barrier layers are provided above. The diffusion barrier layer may be formed using a reactive PVD process wherein material is sputtered from a compound target or co-sputtered from multiple targets in an atmosphere containing a reactive species (e.g. a nitrogen species for nitride-based diffusion barrier layers).

### Memory Array Examples

A brief description of memory arrays will now be described with reference to FIGS. 6A and 6B to provide better understanding to various aspects of thermally isolating structures provided adjacent to nonvolatile memory elements and, in some examples, surrounding the nonvolatile memory elements. Nonvolatile memory elements described above may be used in memory devices or larger integrated circuits (IC) that may take a form of arrays. FIG. 6A illustrates a memory array 600 including nine nonvolatile memory elements 602, in accordance with some embodiments. In general, any number of nonvolatile memory elements may be arranged into one array. Connections to each nonvolatile memory element 602 are provided by signal lines 604 and 606, which may be arranged orthogonally to each other. Nonvolatile memory elements 602 are positioned at crossings of signal lines 604 and 606 that typically define boundaries of each nonvolatile memory element in array 600.

Signal lines 604 and 606 are sometimes referred to as word lines and bit lines. These lines are used to read and write data into each nonvolatile memory element 602 of array 600 by individually connecting nonvolatile memory elements to read and write controllers. Individual nonvolatile memory elements 602 or groups of nonvolatile memory elements 602 can be addressed by using appropriate sets of signal lines 604 and 606. Each nonvolatile memory element 602 typically includes multiple layers, such as top and bottom electrodes, resistance switching layer, embedded resistors, embedded current steering elements, and the like, some of which are further described elsewhere in this document. In some embodiments, a nonvolatile memory element includes multiple resistance switching layers provided in between a crossing pair of signal lines 604 and 606.

As stated above, various read and write controllers may be used to control operations of nonvolatile memory elements 602. A suitable controller is connected to nonvolatile memory elements 602 by signal lines 604 and 606 and may be a part of the same memory device and circuitry. In some embodiments, a read and write controller is a separate memory device capable of controlling multiple memory devices each one containing an array of nonvolatile memory elements. Any suitable read and write controller and array layout scheme may be used to construct a memory device from multiple nonvolatile memory elements. In some embodiments, other electrical components may be associated with the overall array 600 or each nonvolatile memory element 602. For example, to avoid the parasitic-path-problem, i.e., signal bypasses by nonvolatile memory elements in their low resistance state (LRS), serial elements with a particular non-linearity must be added at each node or, more specifically, into each element. Depending on the switching scheme of the nonvolatile memory element, these elements can be diodes or varistor-type elements with a specific degree of non-linearity. In the same other embodiments, an array is organized as an active matrix, in which a transistor is positioned at each node or, more specifically, embedded into each cell to decouple the cell if it is not addressed. This approach significantly reduces crosstalk in the matrix of the memory device.

In some embodiments, a memory device may include multiple array layers as, for example, illustrated in FIG. 6B. In this example, five sets of signal lines 614a-b and 616a-c are shared by four ReRAM arrays 612a-c. As with the previous example, each ReRAM array is supported by two sets of signal lines, e.g., array 612a is supported by 614a and 616a. However, middle signal lines 614a-b and 616b, each is shared by two sets ReRAM arrays. For example, signal line set 614a provides connections to arrays 612a and 612b. Top and bottom sets of signal lines 616a and 616c are only used for making electrical connections to one array. This 3-D arrangement of the memory device should be distinguished from various 3-D arrangements in each individual nonvolatile memory element.

### CONCLUSION

Although the foregoing examples have been described in some detail for purposes of clarity of understanding, the invention is not limited to the details provided. There are many alternative ways of implementing the invention. The disclosed examples are illustrative and not restrictive.

What is claimed:

1. A resistive random access memory cell comprising:
a first electrode;
a second electrode;
a first layer comprising a first metal oxide,
the first layer exhibiting switching between a first resistive state and a second resistive state;
the first layer directly interfacing the first electrode and disposed between
the first electrode and the second electrode; and
a second layer comprising a second metal oxide
the second metal oxide being more oxygen deficient than the first metal oxide,
the second layer disposed between the first electrode and the second electrode, and
the second layer having a thickness greater than a thickness of the first layer.

2. The resistive random access memory cell of claim 1, wherein a concentration of oxygen deficiencies in the first metal oxide is less than 5 atomic percent.

3. The resistive random access memory cell of claim 1, wherein the first metal oxide is a highest oxidation state metal oxide.

4. The resistive random access memory cell of claim 1, wherein the first layer has a thickness of less than 20 Angstroms.

5. The resistive random access memory cell of claim 1, wherein the first layer has a thickness of less than 10 Angstroms.

6. The resistive random access memory cell of claim 1, wherein a concentration of oxygen deficiencies in the second metal oxide is at least 5 atomic percent.

7. The resistive random access memory cell of claim 1, wherein a concentration of oxygen deficiencies in the second metal oxide is less than 10 atomic percent.

8. The resistive random access memory cell of claim 1, wherein a thickness of the second layer is at least 50 Angstroms.

9. The resistive random access memory cell of claim 1, wherein a thickness of the second layer is at less than 1000 Angstroms.

10. The resistive random access memory cell of claim 1, wherein a thickness of the first layer is between five and twenty times smaller than a thickness of the second layer.

11. The resistive random access memory cell of claim 1, wherein the first metal oxide is one of titanium oxide, tantalum oxide, niobium oxide, or aluminum oxide.

12. The resistive random access memory cell of claim 1, wherein the second metal oxide is one of titanium oxide, tantalum oxide, niobium oxide, or aluminum oxide.

13. The resistive random access memory cell of claim 1, wherein the second metal oxide and the first metal oxides are oxides of the same metal.

14. The resistive random access memory cell of claim 1, wherein the second metal oxide and the first metal oxides are oxides of different metals.

15. The resistive random access memory cell of claim 1, wherein the first electrode comprises doped polysilicon.

16. The resistive random access memory cell of claim 1, wherein the first layer has a breakdown field of at least 5 MV/cm.

17. The resistive random access memory cell of claim 1, wherein the first layer has a resistivity of greater than 10̂ 11 Ohm-cm.

18. The resistive random access memory cell of claim 1, further comprising a diffusion barrier layer disposed between the first layer and the second layer.

19. A resistive random access memory cell comprising:
a first electrode, comprising n-doped polysilicon;
a second electrode, comprising titanium nitride;
a first layer comprising tantalum oxide defined by a stoichiometric formula of Ta₂O₅,
the first layer exhibiting resistive switching between a first resistive state and a second resistive state,
the first layer having a thickness of between about 5 Angstroms and 10 Angstroms, and
the first layer directly interfacing the first electrode;
a second layer comprising tantalum oxide defined by a stoichiometric formula of TaO₂,
the second layer having a thickness of between about 30 Angstroms and 100 Angstroms and capable of withstanding a breakdown field of least 5 MV/cm; and
a diffusion barrier layer disposed between the second layer and the second electrode,
the diffusion barrier layer having a thickness of less than 10 Angstroms and comprising tantalum, silicon, and nitrogen.
